(19) United States
(12) Patent Application Publication
(10) Pub. No.: US 2013/0146344 A1
(43) Pub. Date: Jun. 13, 2013

(54) INSULATING RESIN COMPOSITION FOR PRINTED CIRCUIT BOARD AND PRINTED CIRCUIT BOARD INCLUDING THE SAME

(71) Applicant: SAMSUNG ELECTRO-MECHANICS CO., LTD., Suwon (KR)

(72) Inventors: Jeong Kyu LEE, Suwon (KR); Jin Seok Moon, Seoul (KR); Keun Yong Lee, Suwon (KR)

(73) Assignee: SAMSUNG ELECTRO-MECHANICS CO., LTD., Suwon (KR)

(21) Appl. No.: 13/664,901

(22) Filed: Oct. 31, 2012

(30) Foreign Application Priority Data
Oct. 28, 2011 (KR) 10-2011-0111267

(51) Int. Cl. C08L 67/00; C08L 65/00; H05K 1/02; C08L 63/00

(52) U.S. Cl. CPC C08L 67/00; C08L 63/00; C08L 65/00; H05K 1/0213
USPC 174/258; 525/418; 428/416

(57) ABSTRACT

Disclosed herein is an insulating resin composition for a printed circuit board, including 40 to 70 wt % of a liquid crystal oligomer shown in formula 1, 10 to 30 wt % of an epoxy resin, 10 to 30 wt % of a cyanate-based resin, and 0.1 to 0.5 wt % of a curing catalyst, and a printed circuit board including the same.

According to an exemplary embodiment of the present invention, the printed circuit board has electric, thermal, and mechanical stabilities even though the printed circuit board is reduced in weight, thickness, and size. Further, a stable driving property is ensured, dielectricity is low, and attachment strength, chemical resistance, and warpage property are excellent during a board process in the related art.

### CROSS REFERENCE(S) TO RELATED APPLICATIONS

This application claims the benefit under 35 U.S.C. Section 119 of Korean Patent Application Serial No. 10-2011-0111267, entitled “Insulating Resin Composition for Providing Circuit Board and Printed Circuit Board including the Same” filed on Oct. 28, 2011, which is hereby incorporated by reference in its entirety into this application.

### BACKGROUND OF THE INVENTION

1. Technical Field

The present invention relates to an insulating resin composition for a printed circuit board and a printed circuit board including the same.

2. Description of the Related Art

In accordance with development of electronic devices, a printed circuit board has been reduced in weight, thickness, and size. Electric, thermal, and mechanical stabilities of the board are considered critical factors required to satisfy the above requirements.

The printed circuit board includes a copper clad on which a circuit is formed and a polymer resin performing insulation between layers, and insulation thicknesses of a prepreg and a copper clad laminate (CCL) used in the printed circuit board need to be small. Hardness of the board is reduced as the thickness of the circuit board is reduced which causes defects due to warpage when parts are mounted at high temperatures. Accordingly, heat resistance and thermal expansion properties of a thermosetting polymer resin are considered critical factors, and a structure of a polymer, a network of chains of a polymer resin constituting a board composition, and a curing density thereof significantly affects heat resistance and thermal expansion properties during heat curing.

The polymer resin included in the board composition includes a liquid crystal oligomer and an epoxy-based resin as main components. The liquid crystal oligomer includes functional groups such as hydroxy groups at both ends thereof, and the epoxy resin has a multifunctional group. Therefore, when the liquid crystal oligomer and the epoxy-based resin are cured by heat, it is not easy to reduce a coefficient of thermal expansion (CTE) that is one of the important material properties of the circuit board due to a hydroxy group generated during a reaction of the multifunctional epoxy resin and flexibility of a molecular chain of the epoxy-based resin.

### SUMMARY OF THE INVENTION

An object of the present invention is to solve disadvantages of an insulating layer composition of a printed circuit board in the related art and to provide an insulating resin composition for a printed circuit board having a significantly reduced coefficient of thermal expansion.

Another object of the present invention is to provide a copper clad laminate including an insulating layer including the insulating resin composition.

Yet another object of the present invention is to provide a printed circuit board including an insulating layer including the insulating resin composition.

According to an exemplary embodiment of the present invention, there is provided an insulating resin composition for a printed circuit board, including: 40 to 70 wt % of a liquid crystal oligomer including a structure unit of the following formula 1, a structure unit of the following formula 2, and a functional group of the following formula E at at least one end thereof; 10 to 30 wt % of an epoxy resin; 10 to 30 wt % of a cyanate-based resin; and 0.1 to 0.5 wt % of a curing catalyst,

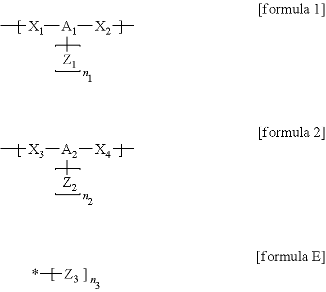

wherein X₁ to X₄ of formulas 1, 2, and E are the same or different, and each C(═O)O, O, C(═O)NR, NR′, or CO (R and R′ are the same or different, and hydrogen, a substituted or unsubstituted C₁ to C₂₀ alkyl group, or a substituted or unsubstituted C₆ to C₃₀ aryl group),

Z₁ to Z₃ are each independently a hydroxy group, a substituted or unsubstituted C₃ to C₃₀ cycloaliphatic group, or a substituted or unsubstituted C₃ to C₃₀ hetero atom-containing cycloaliphatic group,

n₁ to n₃ are each independently an integer of 0 to 3, and a sum total of n₁, n₂, and n₃ may be 1 or more, and

A₁ of formula 1 is any one of the functional groups shown in the following formulas 4-1 to 4-7,

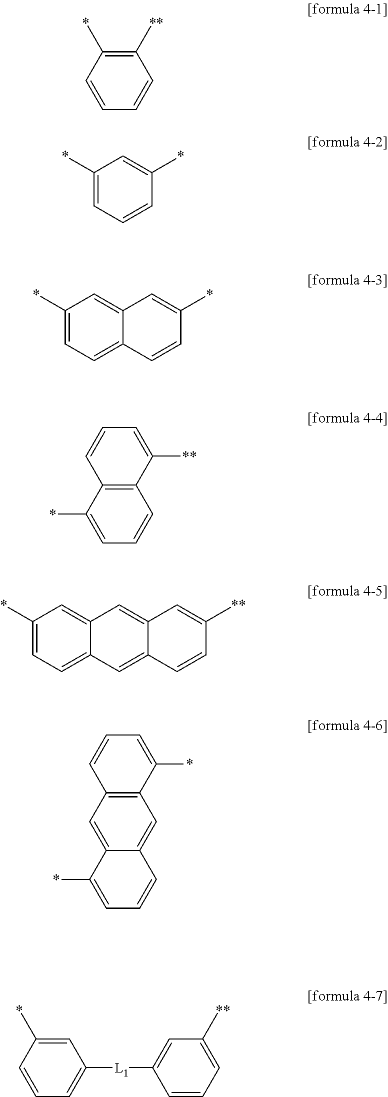

wherein at least one hydrogen of aromatic rings of formulas 4-1 to 4-7 may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1),

L₁ of formula 4-7 is a divalent organic functional group, and

A₂ of formula 2 is a C₂ to C₂₀ alkylene group having any one of the functional groups shown in the following formulas 5-1 to 5-6 or a functional group of the following formula 6,

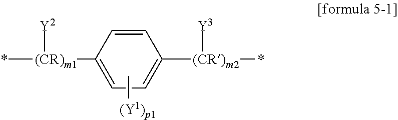

wherein Y¹ to Y³ of formula 5-1 are the same or different, and each hydrogen, a C₁ to C₁₀ alkyl group, or a functional group of the following formula 6, at least one of Y¹ to Y³ is the functional group of the following formula 6, p₁ is an integer of 0 to 4, m₁ and m₂ are the same or different and an integer of 0 to 3, all of p₁, m₁, and m₂ are not 0, and R and R′ are hydrogen or a C₁ to C₁₀ alkyl group,

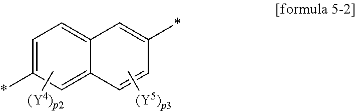

wherein Y⁴ and Y⁵ of formula 5-2 are the same or different, and each hydrogen, a C₁ to C₁₀ alkyl group, or a functional group of the following formula 6, at least one of Y⁴ and Y⁵ is the functional group of the following formula 6, and p₂ and p₃ are an integer of 0 to 3 and both are not 0,

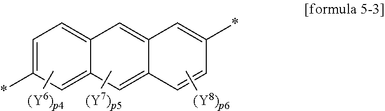

wherein Y⁶ to Y⁸ of formula 5-3 are the same or different, and each hydrogen, a C₁ to C₁₀ alkyl group or a functional group of the following formula 6, at least one of Y⁶ to Y⁸ is the functional group of the following formula 6, p₄ and p₆ are an integer of 0 to 3, p₅ is an integer of 0 to 2, and all of p₄, p₅, and p₆ are not 0,

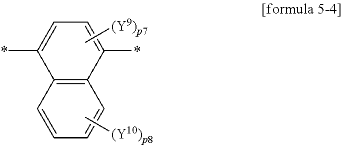

wherein Y⁹ and Y¹⁰ of formula 5-4 are the same or different, and each hydrogen, a C₁ to C₁₀ alkyl group, or a functional group of the following formula 6, at least one of Y⁹ and Y¹⁰ is the functional group of the following formula 6, and p₇ and p₈ are an integer of 0 to 2 and both are not 0,

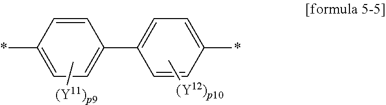

wherein Y¹¹ and Y¹² of formula 5-5 are the same or different, and each hydrogen, a C₁ to C₁₀ alkyl group, or a functional group of the following formula 6, at least one of Y¹¹ and Y¹² is the functional group of the following formula 6, and p₉ and p₁₀ are an integer of 0 to 4 and both are not 0,

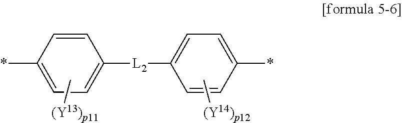

wherein Y¹³ and Y¹⁴ of formula 5-6 are the same or different, and each hydrogen, a C₁ to C₁₀ alkyl group, or a functional group of the following formula 6, at least one of Y¹³ and Y¹⁴ is the functional group of the following formula 6, p₁₁ and p₁₂ are an integer of 0 to 4, L₂ is an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of the following formula 6, or a divalent organic functional group of the following formulas 7-1 to 7-3, and both p₁₁ and p₁₂ are not 0 when L₂ is not substituted with the functional group of the following formula 6, and in formulas 5-1 to 5-6, at least one hydrogen of the aromatic rings may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1),

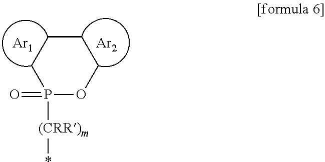

wherein Ar₁ and Ar₂ of formula 6 are a C₄ to C₃₀ substituted or unsubstituted aromatic ring group, R and R′ are the same or different and each hydrogen, a C₁ to C₂₀ alkyl group, or a C₆ to C₃₀ aryl group, and m is an integer of 0 to 3,

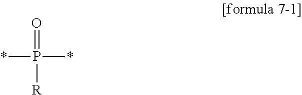

wherein R of formula 7-1 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group,

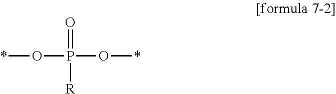

wherein R of formula 7-2 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group

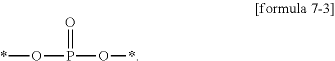

According to the exemplary embodiment of the present invention, the liquid crystal oligomer may have a number average molecular weight of 500 to 10,000 g/mol.

According to the exemplary embodiment of the present invention, the structure unit of the formula 1 may be included in an amount of 5 to 60 mol % based on a total amount of the liquid crystal oligomer and the structure unit of the formula 2 may be included in an amount of 40 to 95 mol % based on the total amount of the liquid crystal oligomer.

According to the exemplary embodiment of the present invention, L₁ of the formula 4-7 may be an ether group, a sulfide group, a ketone group, sulfoxide, a sulfone group, an azo group, a cyanide group, a substituted or unsubstituted C₁ to C₂₀ alkylene group, a substituted or unsubstituted C₁ to C₂₀ alkenylene group, or a substituted or unsubstituted C₆ to C₃₀ arylene group.

According to the exemplary embodiment of the present invention, L₂ of the formula 5-6 may be an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of formula 6, or a divalent organic functional group of the formulas 7-1 to 7-3.

Further, according to the exemplary embodiment of the present invention, formula 6 may be shown in the following formula 11:

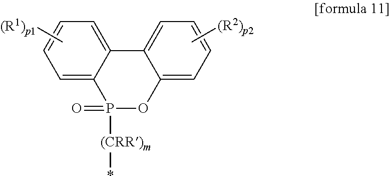

wherein R¹ and R² of formula 11 are the same or different, and each hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1), p₁ and p₂ are an integer of 0 to 4, R and R′ are the same or different, and each hydrogen, a C₁ to C₂₀ alkyl group, or a C₆ to C₃₀ aryl group, and m is an integer of 0 to 3.

Further, according to the exemplary embodiment of the present invention, the liquid crystal oligomer may be shown in the following formula 12:

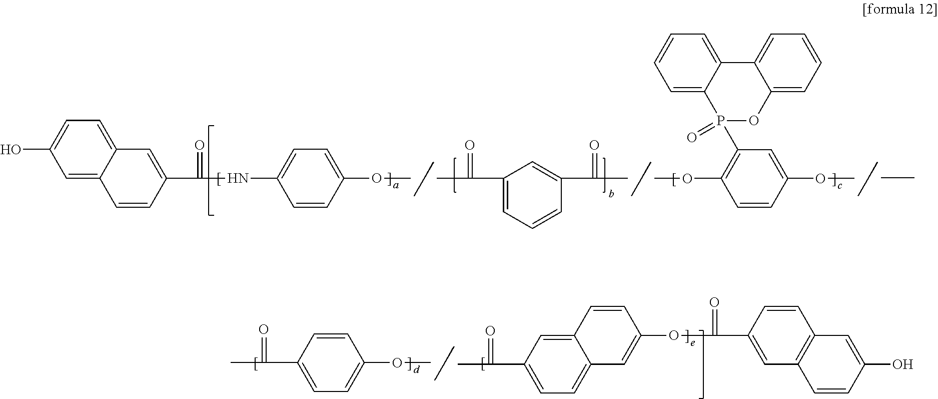

wherein a, b, c, d and e of formula 12 mean a molar ratio of the structure unit and may be determined within the number average molecular weight of the liquid crystal oligomer.

The liquid crystal oligomer shown in formula 12 may have the number average molecular weight of 2000 to 5000 g/mol.

Further, the epxoy resin included in the present invention may be one or more selected from the group consisting of a phenolic glycidyl ether type epoxy resin, a dicyclopentadiene type epoxy resin, a naphthalene type epoxy resin, a dihydroxybenzopyran type epoxy resin, a glycidylamine type epoxy resin, a triphenolmethane type epoxy resin, and a tetraphenylethane type epoxy resin.

Further, the cyanate-based resin included in the present invention may be shown in the following formula 13:

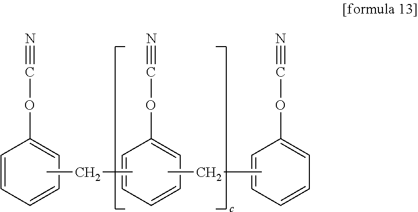

wherein n of formula 13 is preferably 2 to 7.

According to another exemplary embodiment of the present invention, there is provided a copper clad laminate, including: an insulating layer including the insulating resin composition as described above; and a copper clad formed on at least one surface of upper and lower surfaces of the insulating layer.

The insulating layer may further include a reinforcing material.

According to still another exemplary embodiment of the present invention, there is provided a printed circuit board, including: an insulating layer including the insulating resin composition as described above; and a circuit pattern formed on the insulating layer.

The insulating layer may further include a reinforcing material.

### BRIEF DESCRIPTION OF THE DRAWINGS

FIG. 1 is a schematic cross-sectional view of a printed circuit board according to an exemplary embodiment of the present invention.

FIG. 2 is a schematic cross-sectional view of a copper clad laminate according to an exemplary embodiment of the present invention.

### DESCRIPTION OF THE PREFERRED EMBODIMENTS

Hereinafter, exemplary embodiments of the present invention will be described in detail with reference to the accompanying drawings.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, members, elements, and/or groups thereof, but do not preclude the presence or addition of one or more other features, integers, steps, operations, members, elements, and/or groups thereof.

Unless specifically described in the specification, the term “substituted” means that a hydrogen atom of a compound or a functional group is substituted with a substituent group of a halogen (F, Cl, Br, and I), a hydroxy group, an alkoxy group, a nitro group, a cyano group, an amino group, an azido group, an amidino group, a hydrazino group, a hydrazono group, a carbonyl group, a carbamayl group, a thiol group, an ester group, a carboxyl group or a salt thereof, a sulfonic acid group or a salt thereof, a phosphoric acid or a salt thereof, a C₁ to C₂₀ alkyl group, a C₂ to C₁₆ alkynyl group, a C₆ to C₂₀ aryl group, a C₇ to C₁₃ arylalkyl group, a C₁ to C₄ oxyalkyl group, a C₁ to C₂₀ heteroalkyl group, a C₃ to C₂₀ heteroarylalkyl group, a C₃ to C₂₀ cycloalkyl group, a C₃ to C₁₅ cycloalkenyl group, a C₆ to C₁₅ cycloalkynyl group, a heterocycloalkyl group, or a combination thereof.

Unless specifically described in the specification, the term “hetero” means that one to three hetero atoms of N, O, S, Si, or P are present in a ring.

Unless specifically described in the specification, the term “cycloaliphatic group” means a C₃ to C₃₀ cycloalkyl group, a C₃ to C₃₀ cycloalkenyl group, a C₃ to C₃₀ cycloalkynyl group, a C₃ to C₃₀ heterocycloalkyl group, a C₃ to C₃₀ heterocycloalkenyl group, and a C₃ to C₃₀ heterocycloalkynyl group.

Unless specifically described in the specification, the term “aromatic ring group” means a functional group having a ring structure including unsaturated bonds and non-shared electron pairs mixed with each other and delocalization of electrons, or a resonance structure, and a C₆ to C₃₀ aryl group, a C₂ to C₃₀ heteroaryl group, and a C₂ to C₃₀ heterocycloalkenyl group.

The present invention relates to an insulating layer resin composition for a printed circuit board, including a liquid crystal oligomer, a cyanate-based resin, an epoxy resin, and a curing catalyst to improve a low thermal expansion property and heat resistance.

The liquid crystal oligomer according to the present invention is subjected to a curing reaction in conjunction with the cyanate-based resin or the epoxy resin in the composition, and preferably includes a structure unit of the following formula 1, a structure unit of the following formula 2, and a functional group of the following formula E at at least one end thereof:

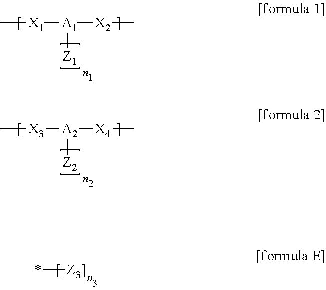

wherein X₁ to X₄ of formulas 1, 2, and E are the same or different, and C(═O)O, O, C(═O)NR, NR′, or CO (R and R′ are the same or different, and hydrogen, a substituted or unsubstituted C₁ to C₂₀ alkyl group, or a substituted or unsubstituted C₆ to C₃₀ aryl group),

Z₁ to Z₃ are each independently a hydroxy group, a substituted or unsubstituted C₃ to C₃₀ cycloaliphatic group, or a substituted or unsubstituted C₃ to C₃₀ hetero atom-containing cycloaliphatic group,

n₁ to n₃ are each independently an integer of 0 to 3, and a sum total of n₁, n₂, and n₃ may be 1 or more, and

A₁ of formula 1 is any one of the functional groups shown in the following formulas 4-1 to 4-7,

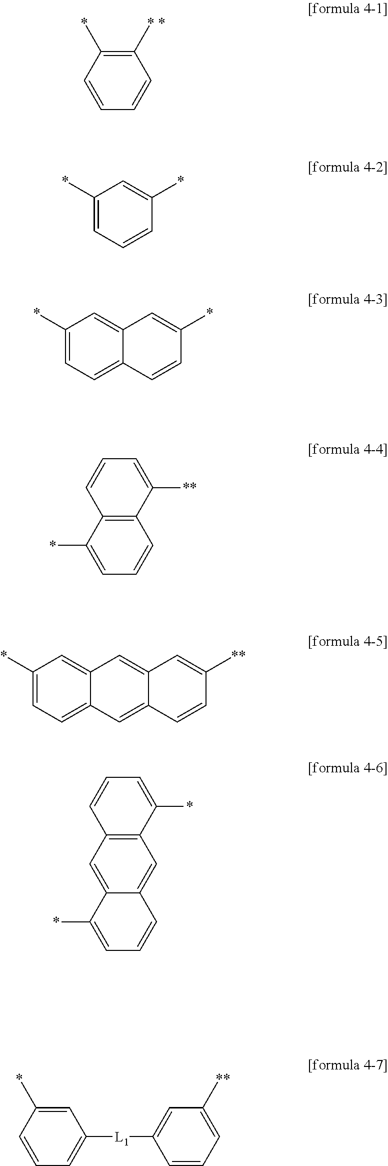

wherein at least one hydrogen of aromatic rings of formulas 4-1 to 4-7 may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1),

L₁ of formula 4-7 is a divalent organic functional group, and

A₂ of formula 2 is a C₂ to C₂₀ alkylene group having any one of functional groups shown in the following formulas 5-1 to 5-6 or a functional group of the following formula 6,

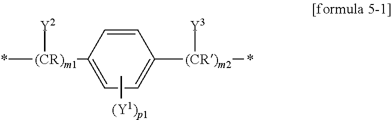

wherein Y¹ to Y³ of formula 5-1 are the same or different, and each hydrogen, a C₁ to C₁₀ alkyl group, or a functional group of the following formula 6, at least one of Y¹ to Y³ is the functional group of the following formula 6, p₁ is an integer of 0 to 4, m₁ and m₂ are the same or different and an integer of 0 to 3, all of p₁, m₁, and m₂ are not 0, and R and R′ are hydrogen or a C₁ to C₁₀ alkyl group,

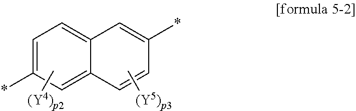

wherein Y⁴ and Y⁵ of formula 5-2 are the same or different, and each hydrogen, a C₁ to C₁₀ alkyl group, or a functional group of the following formula 6, at least one of Y⁴ and Y⁵ is the functional group of the following formula 6, and p₂ and p₃ are an integer of 0 to 3 and both are not 0,

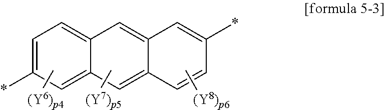

wherein Y⁶ to Y⁸ of formula 5-3 are the same or different, and each hydrogen, a C₁ to C₁₀ alkyl group or a functional group of the following formula 6, at least one of Y⁶ to Y⁸ is the functional group of the following formula 6, p₄ and p₆ are an integer of 0 to 3, p₅ is an integer of 0 to 2, and all of p₄, p₅, and p₆ are not 0,

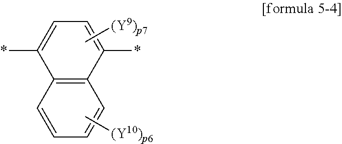

wherein Y⁹ and Y¹⁰ of formula 5-4 are the same or different, and each hydrogen, a C₁ to C₁₀ alkyl group, or a functional group of the following formula 6, at least one of Y⁹ and Y¹⁰ is the functional group of the following formula 6, and p₇ and p₈ are an integer of 0 to 2 and both are not 0,

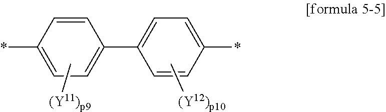

wherein Y¹¹ and Y¹² of formula 5-5 are the same or different, and each hydrogen, a C₁ to C₁₀ alkyl group, or a functional group of the following formula 6, at least one of Y¹¹ and Y¹² is the functional group of the following formula 6, and p₉ and p₁₀ are an integer of 0 to 4 and both are not 0,

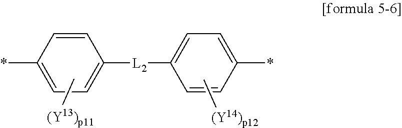

wherein Y¹³ and Y¹⁴ of formula 5-6 are the same or different, and each hydrogen, a C₁ to C₁₀ alkyl group, or a functional group of the following formula 6, at least one of Y¹³ and Y¹⁴ is the functional group of the following formula 6, p₁₁ and p₁₂ are an integer of 0 to 4, L₂ is an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of the following formula 6, or a divalent organic functional group of the following formulas 7-1 to 7-3, and both p₁₁ and p₁₂ are not 0 when L₂ is not substituted with the functional group of the following formula 6, and

in formulas 5-1 to 5-6, at least one hydrogen of the aromatic rings may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1),

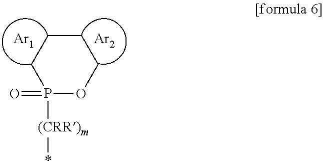

wherein Ar₁ and Ar₂ of formula 6 are a C₄ to C₃₀ substituted or unsubstituted aromatic ring group, R and R′ are the same or different and each hydrogen, a C₁ to C₂₀ alkyl group, or a C₆ to C₃₀ aryl group, and m is an integer of 0 to 3,

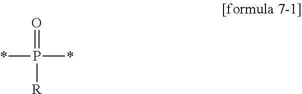

wherein R of formula 7-1 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group,

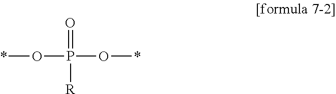

wherein R of formula 7-2 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group

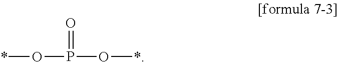

According to the exemplary embodiment of the present invention, L₁ of formula 4-7 is an ether group, a sulfide group, a ketone group, sulfoxide, a sulfone group, an azo group, a cyanide group, a substituted or unsubstituted C₁ to C₂₀ alkylene group, a substituted or unsubstituted C₁ to C₂₀ alkenylene group, or a substituted or unsubstituted C₆ to C₃₀ arylene group. Specific examples of L₁ are any one of groups shown in the following formulas 9-1 to 9-10.

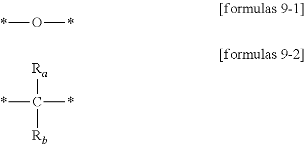

wherein Ra and Rb of formula 9-2 are each independently hydrogen, a halogen, a C₁ to C₅ alkyl group, a C₁ to C₅ haloalkyl group, or Z₁ (Z₁ is defined in formula 1).

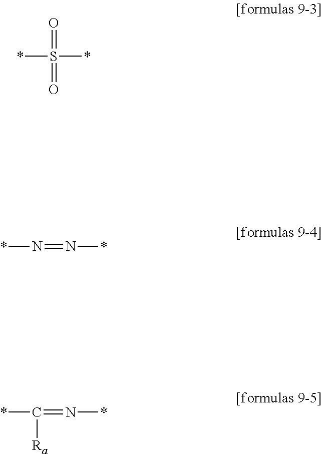

wherein Ra of formula 9-5 is hydrogen, a halogen, a C₁ to C₅ alkyl group, a C₁ to C₅ haloalkyl group, or Z₁ (Z₁ is defined in formula 1).

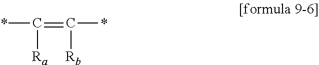

wherein Ra and Rb of formula 9-6 are each independently hydrogen, a halogen, a C₁ to C₅ alkyl group, a C₁ to C₅ haloalkyl group, or Z₁ (Z₁ is defined in formula 1).

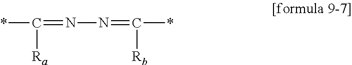

wherein Ra and Rb of formula 9-7 are each independently hydrogen, a halogen, a C₁ to C₅ alkyl group, a C₁ to C₅ haloalkyl group, or Z₁ (Z₁ is defined in formula 1).

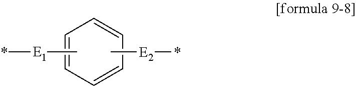

wherein E₁ and E₂ of formula 9-8 are the same or different, and a connection group selected from the group consisting of a single bond, an ether group, an ester group, a ketone group, a sulfide group, sulfoxide, and a sulfone group.

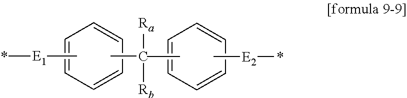

wherein Ra and Rb of formula 9-9 are each independently hydrogen, a halogen, a C₁ to C₅ alkyl group, a C₁ to C₅ haloalkyl group, or Z₁ (Z₁ is defined in formula 1), and E₁ and E₂ are the same or different, and a connection group selected from the group consisting of a single bond, an ether group, an ester group, a ketone group, a sulfide group, sulfoxide, and a sulfone group.

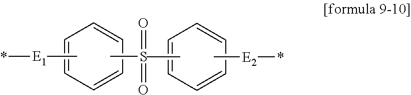

wherein E₁ and E₂ of formula 9-10 are each independently a connection group selected from the group consisting of a single bond, an ether group, an ester group, a ketone group, a sulfide group, sulfoxide, and a sulfone group.

In formulas 9-8 to 9-10, at least one hydrogen of the aromatic rings is substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1).

According to the exemplary embodiment of the present invention, L₂ of formula 5-6 is an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of the following formula 6, or a divalent organic functional group of formulas 7-1 to 7-3.

Specific examples of L₂ are any one of the groups shown in formulas 9-1 to 9-10. In formulas 9-2, 9-5, 9-6, 9-7, and 9-9, Ra and Rb are each independently hydrogen, a halogen, a C₁ to C₅ alkyl group, a C₁ to C₅ haloalkyl group, Z₁ (Z₁ is defined in formula 1), or a functional group of formula 6, and in formulas 9-8 to 9-10, at least one hydrogen of the aromatic rings is substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, Z₁ (Z₁ is defined in formula 1), or a functional group of formula 6.

Further, according to the exemplary embodiment of the present invention, formula 6 is shown in the following formula 11:

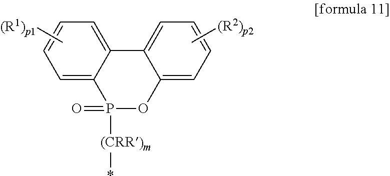

R¹ and R² of formula 11 are the same or different, and each hydrogen, a halogen, a substituted or unsubstituted C₁ to C₂₀ alkyl group, a substituted or unsubstituted C1 to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is as defined in the formula 1), p₁ and p₂ are an integer of 0 to 4, R and R′ are the same or different, and each hydrogen, a C₁ to C₂₀ alkyl group, or a C₆ to C₃₀ aryl group, and m is an integer of 0 to 3.

According to the exemplary embodiment of the present aspect, the liquid crystal oligomer includes a hydroxy group in one or more of a side chain and an end thereof. Further, the liquid crystal oligomer includes a functional group having phosphorus in a main chain or a side chain thereof. According to the exemplary embodiment of the present invention, the liquid crystal oligomer includes the hydroxy group in one or more of the side chain and the end thereof to perform the crosslinking reaction of the liquid crystal oligomer and the epoxy resin instead of the crosslinking reaction of the liquid crystal oligomers, thus curing the insulating resin composition. Further, the liquid crystal oligomer includes a functional group having phosphorus in a main chain or a side chain thereof to increase flame retardancy of the insulating resin composition.

According to the exemplary embodiment of the present invention, the liquid crystal oligomer may have a number average molecular weight of 500 to 10,000 g/mol, and when the liquid crystal oligomer has the number average molecular weight in the above range, the liquid crystal oligomer may have an appropriate crosslinking density and a solubility property to the solvent is excellent, such that the content of solid may be sufficient when the liquid crystal oligomer is impregnated in a network structure to produce a prepreg to ensure excellent physical properties.

According to the exemplary embodiment of the present invention, the structure unit of formula 1 may be included in an amount of 5 to 60 mol % based on a total amount of the liquid crystal oligomer and the structure unit of formula 2 may be included in an amount of 40 to 95 mol % based on the total amount of the liquid crystal oligomer. When the structure unit of formula 1 and the structure unit of formula 2 are included in the above amount range, solubility of the liquid crystal oligomer is increased. Further, the insulating resin composition is cured without the crosslinking reaction in the liquid crystal oligomer to improve mechanical properties.

Further, according to the preferred exemplary embodiment of the present invention, the liquid crystal oligomer is shown in the following formula 12:

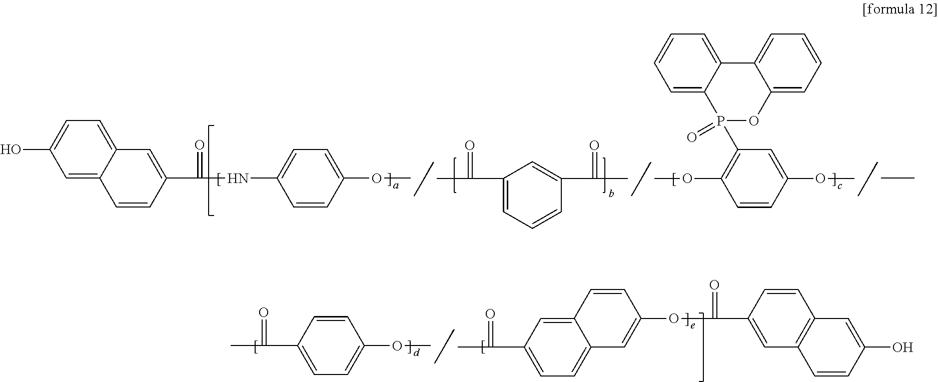

a, b, c, d and e of formula 12 mean a molar ratio of the structure unit and may be determined within the number average molecular weight of the liquid crystal oligomer.

The liquid crystal oligomer shown in formula 12 includes hydroxy groups at both ends thereof and a functional group including phosphorus at a side chain thereof.

According to the exemplary embodiment of the present invention, the liquid crystal oligomer shown in formula 12 is included to increase solubility. Further, the crosslinking reaction of the liquid crystal oligomer and the epoxy resin is performed instead of the crosslinking reaction of the liquid crystal oligomers to cure the insulating resin composition, thereby improving mechanical properties.

The liquid crystal oligomer shown in formula 12 may have the number average molecular weight of 2000 to 5000 g/mol to maintain a soluble property and ensure a crosslinking density.

The liquid crystal oligomer shown in formula 1 may be included in the content of 40 to 70 wt % based on the total content of the composition of circuit board, when the content of the liquid crystal oligomer is less than 40 wt %, a thermal property is reduced, and when the content is more than 70 wt %, chemical resistance is reduced, which is not preferable.

Further, the insulating layer resin composition of the printed circuit board of the present invention includes the epoxy resin to provide attachment strength. Illustrating and non-limiting examples of the epoxy resin include a phenolic glycidyl ether type epoxy resin such as a phenol novolac type epoxy resin, a cresol novolac type epoxy resin, a naphthol-modified novolac type epoxy resin, a bisphenol A type epoxy resin, a bisphenol F type epoxy resin, a biphenyl type epoxy resin, and a triphenyl type epoxy resin; a dicyclopentadiene type epoxy resin having a dicyclopentadiene skeleton; a naphthalene type epoxy resin having a naphthalene skeleton; a dihydroxybenzopyran type epoxy resin; a glycidylamine type epoxy resin including polyamine such as diaminophenylmethane as a raw material; a triphenolmethane type epoxy resin; a tetraphenylethane type epoxy resin; or a mixture thereof.

More specific examples of the epoxy resin include N,N,N′,N′-tetraglycidyl-4,4′-methylenebisbenzenamine, glycidyl ether type o-cresol-formaldehyde novolac (polyglycidyl ether of o-cresol-formaldehyde novolac), or a mixture thereof.

The epoxy resin may be in included in the content of 10 to 30 wt % in the insulating layer resin composition of the printed circuit board, when the epoxy resin is included in the above content range, attachment strength of the insulating composition to metal such as copper is increased, and chemical resistance, thermal property, and dimensional stability are increased.

Further, the cyanate-based resin of the present invention is shown in the following formula 13:

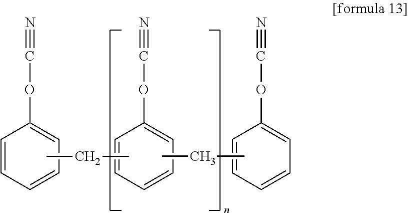

wherein n of formula 13 may be 2 to 7.

The cyanate resin is included in the composition for circuit board, and cyanate functional groups are reacted with each other during a thermal curing reaction to form a cyclic structure, thus ensuring a low coefficient of thermal expansion and high heat resistance.

Further, the cyanate functional group of the cyanate resin is reacted with the hydroxy group of the liquid crystal oligomer or the epoxide group of the epoxy resin to contribute to forming a network structure of the liquid crystal oligomer/epoxy resin/cyanate resin.

The cyanate resin may be included in the content of 10 to 30 wt % based on the total content of the composition for circuit board, when the content of the cyanate resin is less than 10 wt %, heat resistance is reduced, and when the content of the cyanate resin is more than 30 wt %, crosslinking density and attachment strength are reduced, which is not preferable.

The insulating resin composition for the printed circuit board according to the exemplary embodiment of the present invention includes the curing catalyst.

Illustrating and non-limiting examples of the curing catalyst include 2-methylimidazole, 2-phenylimidazole, 2-phenyl-4-phenylimidazole, bis(2-ethyl-4-methylimidazole), 2-phenyl-4-methyl-5-hydroxymethylimidazole, 2-phenyl-4,5-dihydroxymethylimidazole, triazine-added imidazole, methylnadic anhydride, dicyandiamide, phthalic anhydride, tetrahydrophthalic anhydride, methylbutyltetrahydrophthalic anhydride, hexahydrophthalic anhydride, methylhydrophthalic anhydride, trimethylic anhydride, pyrometallic anhydride, benzophenontetracarboxylic anhydride, and a mixture thereof.

The content of the curing catalyst is 0.1 to 0.5 wt % based on the total content of the composition. When the content of the curing catalyst is less than 0.1 wt %, a crosslinking reaction is reduced, and when the content is more than 0.5 wt %, heat resistance is reduced.

The insulating resin composition for the printed circuit board according to the exemplary embodiment of the present invention may further include the solvent.

A polar non-protonic solvent may be used as the solvent, and illustrating, but non-limiting examples of the solvent include a halogen-based solvent such as 1-chlorobutane, chlorobenzene, 1,1-dichloroethane, 1,2-dichloroethane, chloroform, and 1,1,2,2-tetrachloroethane; an ether-based solvent such as diethyl ether, tetrahydrofuran, and 1,4-dioxane; a ketone-based solvent such as methyl ethyl ketone (MEK), acetone, and cyclohexanone; an acetate-based solvent such as propylene glycol monomethyl ether acetate (PGMEA); an ester-based solvent such as ethyl acetate; a lactone-based solvent such as γ-butyrolactone; a carbonate-based solvent such as ethylene carbonate and propylene carbonate; an amine-based solvent such as triethylamine and pyridine; a nitrile-based solvent such as acetonitrile; an amide-based solvent such as N,N′-dimethylformamide (DMF), N,N′-dimethylacetamide (DMAc), tetramethylurea, and N-methylpyrrolidone (NMP); a nitro-based solvent such as nitromethane and nitrobenzene; a sulfide-based solvent such as dimethyl sulfoxide (DMSO) and sulfolane; a phosphoric acid-based solvent such as hexamethyl phosphoric amide and tri-n-butyl phosphate; or a combination thereof.

Further, the insulating resin composition for the printed circuit board according to the exemplary embodiment of the present invention may further include additives such as fillers, softeners, plasticizers, antioxidants, flame retardants, flame retardant adjuvants, lubricants, antistatic agents, coloring agents, thermal stabilizers, light stabilizers, UV absorbers, coupling agents, or antisettling agents.

The filler includes an organic filler or an inorganic filler. Illustrating and non-limiting examples of the organic filler include epoxy resin powder, melamine resin powder, urea resin powder, benzoguanamine resin powder, and styrene resin. Illustrating and non-limiting examples of the inorganic filler include natural silica, fused silica, amorphous type silica, hollow silica, aluminum hydroxide, boehmite, magnesium hydroxide, molybdenum oxide, zinc molybdate, zinc borate, zinc stannate, aluminum borate, potassium titanate, magnesium sulfate, silicon carbide, zinc oxide, silicon nitride, silicon oxide, aluminum titanate, barium titanate, barium strontium titanate, aluminum oxide, alumina, clay, kaolin, talc, calcined clay, calcined kaolin, calcined talc, mica, and short glass fibers. The organic filler and the inorganic filler are used alone or in combination.

Illustrating and non-limiting examples of the plasticizer include polyethylene glycol, polyamide oligomer, ethylenebisstearamide, phthalate ester, polystyrene oligomer, liquid paraffin, polyethylene wax, and silicon oil. The examples of the plasticizer are used alone or in combination.

Illustrating and non-limiting examples of the antioxidant include a phosphorus-containing antioxidant, a phenol-based antioxidant, and a sulfur-containing antioxidant. The examples of the antioxidant are used alone or in combination.

The above-mentioned constituent components are blended using various methods such as mixing at normal temperature or melt mixing to produce the insulating resin composition for the printed circuit board according to the exemplary embodiment of the present invention.

The insulating layer of the printed circuit board includes the insulating resin composition according to the exemplary embodiment of the present invention. Specifically, the insulating resin composition layer is cast on the substrate to form a thin film and the solvent is removed to form the insulating layer on the substrate, but this constitution is not intended to limit the present invention. Examples of the substrate include a metal clad such as a copper clad, an aluminum clad, a gold clad, and a silver clad, a glass board, or a PET film.

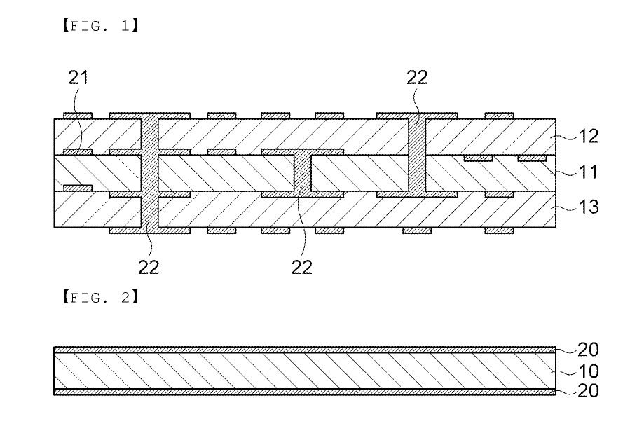

FIG. 1 is a schematic sectional view of the printed circuit board according to the exemplary embodiment of the present invention.

Referring to FIG. 1, the printed circuit board according to the present exemplary embodiment includes insulating layers 11, 12, and 13; and circuit patterns 21 and 22 formed on one side or both sides of the insulating layer. More specifically, the first insulating layer 11 is provided, and the second insulating layer 12 and the third insulating layer 13 are laminated on upper and lower sides of the first insulating layer 11, respectively, to form a main body of the board. Further, a horizontal wire 21 is formed on the first to the third insulating layers 11, 12, and 13, and a via electrode 22 is formed to connect the horizontal wires.

In the present exemplary embodiment, a four-layered printed circuit board is shown, but the present invention is not limited thereto, and a single-layered or multilayered wire board may be used according to the number of insulating layers to be used and a circuit pattern to be formed.

The circuit patterns 21 and 22 are formed and laminated on the insulating layers 11, 12, and 13 by plating to form a printed circuit board.

Further, the insulating layers 11, 12, and 13 of the printed circuit board may be a prepreg including the insulating resin composition and the reinforcing material.

The insulating resin composition and the reinforcing material are mixed to form the prepreg. More specifically, the insulating resin composition is applied or impregnated on the reinforcing material, and cured, and the solvent is removed to produce the prepreg. Illustrating and non-limiting examples of the impregnation process include a dip coating process and a roll coating process.

Examples of the reinforcing material include glass clothes, alumina glass clothes, glass non-woven fabrics, cellulose non-woven fabrics, carbon clothes, and polymer clothes. Other examples thereof include glass fibers, silica glass fibers, carbon fibers, alumina fibers, silicon carbide fibers, asbestos, rock wools, mineral wools, plaster, woven fabrics or non-woven fabrics thereof, aromatic polyamide fibers, polyimide fibers, liquid crystal polyester, polyester fibers, fluorine fibers, polybenzoxazole fibers, glass fibers having polyamide fibers, glass fibers having carbon fibers, glass fibers having polyimide fibers, glass fibers having aromatic polyester, glass papers, mica papers, alumina papers, craft papers, cotton papers, and paper-glass bond papers. The examples thereof may be used in combination.

The glass fiber is 5 to 200 μm in diameter.

The insulating resin composition is impregnated in the content of about 40 to 300 parts by weight based on 100 parts by weight of the reinforcing material. When the insulating resin composition is impregnated within the above content range, mechanical strength and dimensional stability of the prepreg are increased. Further, an adhesive property of the prepreg is increased to increase a contact property between the prepregs.

FIG. 2 is a schematic sectional view of a copper clad laminate according to an exemplary embodiment of the present invention.

The copper clad laminates (CCL) are laminated to form the printed circuit board according to the exemplary embodiment of the present invention.

Referring to FIG. 2, the copper clad laminate includes an insulating layer 10 and copper clads 20 formed on both sides of the insulating layer. Further, the copper clad may be formed only on one side of the insulating layer, not shown in the drawings.

The insulating layer 10 includes the insulating resin composition according to the exemplary embodiment of the present invention or the prepreg including the insulating resin composition and the reinforcing material.

The copper clad 20 is formed on the insulating layer 10 and heat treated to form the copper clad laminate. The copper clad 20 of the copper clad laminate is patterned to form a circuit pattern.

In accordance with the development of electronic devices, a printed circuit board is reduced in weight, thickness, and size, and wiring of the printed circuit board becomes complicated and highly dense. Further, electric, thermal, and mechanical stabilities of the printed circuit board are considered critical factors to ensure stability and reliability of the electronic devices.

In other words, an insulating layer of a printed circuit board needs to be thin while the same or higher electric, thermal, and mechanical properties are ensured as compared to a printed circuit board in the related art. Further, driving stability needs to be ensured during a board process in the related art while the insulating layer is slim.

When the insulating layer is slim, warpage occurs due to a small thickness thereof during driving of the board process, and chemical resistance to acidic chemicals is significantly reduced. In this connection, defects of products, failure in equipment, and contamination of liquid occur to incur a serious loss.

When chemical resistance of the printed circuit board is reduced, the circuit formed on the printed circuit board becomes thin or is not removed, and defects such as voids and peeling occur during a lamination process.

Further, when the printed circuit board does not have a predetermined mechanical property, a corner thereof is bent or a warpage occurs during the driving of the board process. When a predetermined warpage property is not ensured, a manual amendment operation needs to be performed for every unit process and a lead time is increased which reduces productivity. Further, when the board is rolled, damage to a conveyer roll occurs, and defects are continuously formed on subsequently provided boards.

However, the insulating resin composition according to the exemplary embodiment of the present invention includes most preferable type and content of constitution components to ensure excellent heat resistance and mechanical strength and low dielectricity and hygroscopicity. Accordingly, even if the board production process in the related art is used, warpage property and chemical resistance are ensured so as to provide driving stability.

Further, the insulating layer including the insulating resin composition according to the exemplary embodiment of the present invention has increased attachment strength. Accordingly, attachment strength is favorable, and embedding property of a pattern, welding heat resistance, and wet endurance are satisfied at a heat treatment temperature of 200° C. or less. Further, electric property, dimensional stability, chemical resistance, and mechanical property are excellent.

Hereinafter, the present invention will be described in detail in light of the examples. The present invention may, however, be embodied in many different forms and should not be construed as being limited to the examples set forth herein. Rather, these examples are provided such that this disclosure will be thorough and complete and will fully convey the concept of the present invention to those skilled in the art.

### Example 1

### Production of the Prepreg

60 wt % of the liquid crystal oligomer (the number average molecular weight was 3900 g/mol) shown in formula 12-1, 20 wt % of N,N,N′,N′-tetraglycidyl-4,4′-methylenebisbenzenamine, 20 wt % of the phenol novolac cyanate ester resin, and 0.2 wt % of dicyandiamide as the curing catalyst were added to N,N′-dimethylacetamide (DMAc) so that the content of solid was 55 wt % to produce the insulating resin composition mixture solution (vanish).

The glass fiber (1078 manufactured by Baotek Industrial Material Ltd., and 1037 manufactured by Asahi, Co., Ltd.) was uniformly impregnated using the mixture solution. The glass fiber impregnated in the mixture solution passed through the heating zone at 200° C. to be semicured, thus obtaining the prepreg.

In this connection, the weight of the polymer was 54 to 56 wt % based on the total weight of the prepreg.

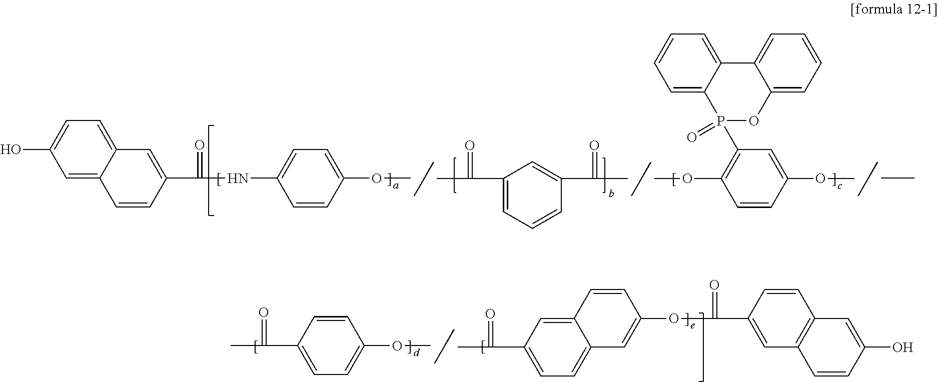

a, b, c, d, and e of formula 12-1 mean a molar ratio of the repeating unit and depend on the content of a starting material.

### Example 2

### Production of the Prepreg

The same procedure as example 1 was repeated to produce the insulating resin composition mixture solution (vanish) including 53 wt % of the solid, except that the liquid crystal oligomer having the number average molecular weight of 4100 g/mol shown in formula 12-1 was used, and o-cresol-formaldehyde novolac (polyglycidyl ether of o-cresol-formaldehyde novolac, YDCN-500P-1P manufactured by Kukdo Chemical, Co., Ltd.) was used as the epoxy resin.

The glass fibers (1078 manufactured by Baotek Industrial Material Ltd., and 1037 manufactured by Asahi, Co., Ltd.) were uniformly impregnated using the mixture solution. The glass fiber impregnated in the mixture solution passed through the heating zone at 200° C. to be semicured, thus obtaining the prepreg.

In this connection, the weight of the polymer was 56 wt % based on the total weight of the prepreg.

### Example 3

### Production of the Prepreg

60 wt % of the liquid crystal oligomer shown in formula 12-1 used in example 1, 20 wt % of YDF-170 (manufactured by Kukdo Chemical, Co., Ltd., the product of the formaldehyde oligomer reaction of phenol), 20 wt % of the phenol novolac cyanate ester resin, and 0.2 wt % of dicyandiamide as the curing catalyst were added to N,N′-dimethylacetamide (DMAc) so that the content of solid was 58 wt % to produce the insulating resin composition mixture solution (vanish).

The glass fibers (1078 manufactured by Baotek Industrial Material Ltd., and 1037 manufactured by Asahi, Co., Ltd.) were uniformly impregnated using the mixture solution. The glass fiber impregnated in the mixture solution passed through the heating zone at 200° C. to be semicured, thus obtaining the prepreg.

In this connection, the weight of the polymer was 55 wt % based on the total weight of the prepreg.

### Comparative Example 1

### Production of the Prepreg

The same procedure as example 1 was repeated to produce the insulating resin composition mixture solution (vanish) including 55 wt % of the solid, except that the phenol novolac cyanate ester resin as the cyanate-based resin was not included and 40 wt % of N,N,N′,N′-tetraglycidyl-4,4′-methylenebisbenzenamine was added.

The glass fibers (1078 manufactured by Baotek Industrial Material Ltd., and 1037 manufactured by Asahi, Co., Ltd.) were uniformly impregnated using the mixture solution. The glass fiber impregnated in the mixture solution passed through the heating zone at 200° C. to be semicured, thus obtaining the prepreg.

In this connection, the weight of the polymer was 54 to 56 wt % based on the total weight of the prepreg.

### Test Example 1

### Evaluation of the Thermal Property of the Prepreg

The glass transition temperature Tg of the prepreg sample produced in examples 1 to 3 and comparative example 1 was measured using the dynamic mechanical analyzer (DMA, TA Instruments DMA Q800), the thermal decomposition temperature Td was measured using the thermogravimetric analyzer (TGA, TA Instruments TGA DTA Q600), and the coefficient of thermal expansion (CTE) was measured using the thermomechanical analyzer (TMA, TA Instruments TMA Q400) in a nitrogen atmosphere while the temperature was increased at a rate of 10° C./min, and the results are described in the following Table 1.

### Test Example 2

### Evaluation of the Peel Strength of the Copper Clad of the Prepreg

The copper clad having the width of 1 cm was peeled from the surface of the copper clad laminate, and the peel strength of the copper clad to the insulating layer was measured using the tensile strength measuring device (universal testing machine, UTM), and the results are described in the following Table 1 (90° Peel Test, Crosshead speed: 50 mm/min).

TABLE 1

| | | | | Comparative |
|---|---|---|---|---|
| | Example 1 | Example 2 | Example 3 | example 1 |
| Glass transition | 255 | 245 | 250 | 245 |
| temperature (° C.) | | | | |
| Coefficient of thermal | 10 | 12 | 11 | 12 |
| expansion (ppm/° C.) | | | | |
| Peel strength (kgf/cm) | 1.6 | 1.7 | 1.7 | 1.6 |
| Thermal | 325 | 310 | 315 | 305 |
| decomposition | | | | |
| temperature | | | | |
| (5 wt % weight | | | | |
| reduction temperature, | | | | |
| ° C.) | | | | |

From the results of Table 1, it was confirmed that the prepreg produced using the insulating layer resin composition of examples 1 to 3 including the liquid crystal oligomer, the epoxy resin, the cyanate-based resin, and the curing catalyst according to the present invention had the increased thermal decomposition temperature as compared to the prepreg produced using the insulating layer resin composition not including the cyanate-based resin of comparative example 1.

Particularly, it can be seen that the coefficient of thermal expansion is significantly increased due to the combination of the epoxy resin and the cyanate-based resin of example 1.

Therefore, the prepregs having excellent heat resistance, reliability over a long period of time, and warpage property according to examples 1 to 3 of the present invention are applied to an ultra-highly dense printed circuit board.

A resin composition for a printed circuit board according to an exemplary embodiment of the present invention increases a coefficient of thermal expansion and thermal properties (glass transition temperature and thermal decomposition temperature) of a prepreg to provide a slim and highly dense printed circuit board having excellent heat resistance and linear expansion property.

According to the exemplary embodiment of the present invention, a printed circuit board is reduced in weight, thickness, and size while the same or higher electric, thermal, and mechanical properties are ensured as compared to a printed circuit board in the related art.

Further, a mechanical property is excellent while an insulating layer of the printed circuit board is slim to ensure driving stability during a board process in the related art.

According to the exemplary embodiment of the present invention, even though the insulating layer of the printed circuit board is slim, a warpage property is not reduced, and chemical resistance is excellent to alkali or acidic chemicals. Accordingly, the circuit formed on the printed circuit board does not become thin and is not removed, and defects such as voids and peels are prevented from being formed during a lamination process. Further, failure in equipment and contamination of liquid are prevented, and productivity is increased.

According to the exemplary embodiment of the present invention, excellent heat resistance and mechanical strength and low dielectricity and hygroscopicity are ensured. Further, attachment strength is excellent, embedding property of a pattern, welding heat resistance, and wet endurance are satisfied, and electric property, dimensional stability, chemical resistance, and mechanical property are excellent.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. An insulating resin composition for a printed circuit board, comprising:
40 to 70 wt % of a liquid crystal oligomer including a structure unit of the following formula 1, a structure unit of the following formula 2, and a functional group of the following formula E at at least one end thereof;
10 to 30 wt % of an epoxy resin;
10 to 30 wt % of a cyanate-based resin; and
0.1 to 0.5 wt % of a curing catalyst, 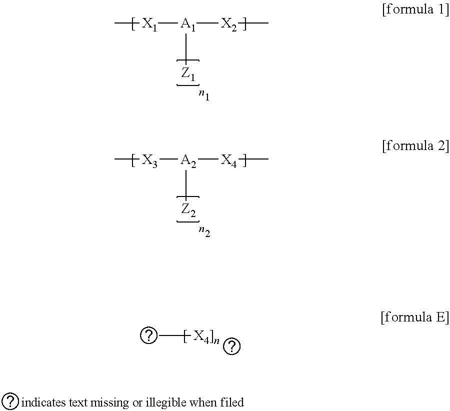
wherein X₁ to X₄ of formulas 1, 2, and E are the same or different, and C(═O)O, O, C(═O)NR, NR′, or CO (R and R′ are the same or different, and hydrogen, a substituted or unsubstituted C₁ to C₂₀ alkyl group, or a substituted or unsubstituted C₆ to C₃₀ aryl group),
Z₁ to Z₃ are each independently a hydroxy group, a substituted or unsubstituted C₃ to C₃₀ cycloaliphatic group, or a substituted or unsubstituted C₃ to C₃₀ hetero atom-containing cycloaliphatic group,
n₁ to n₃ are each independently an integer of 0 to 3, and a sum total of n₁, n₂, and n₃ may be 1 or more, and
A₁ of formula 1 is any one of functional groups shown in the following formulas 4-1 to 4-7, 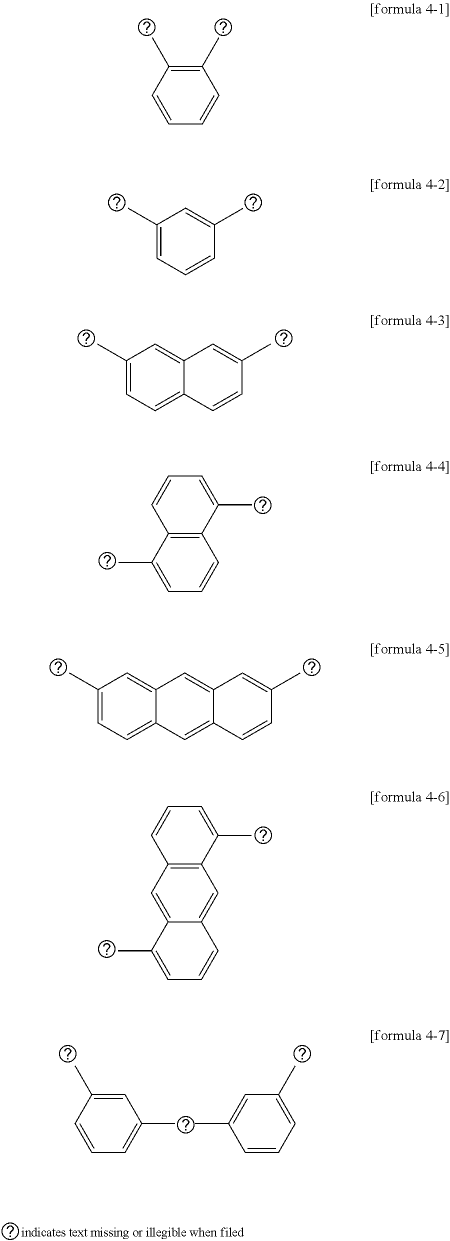
wherein at least one hydrogen of aromatic rings of formulas 4-1 to 4-7 may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1),
L₁ of formula 4-7 is a divalent organic functional group, and
A₂ of formula 2 is a C₂ to C₂₀ alkylene group having any one of functional groups shown in the following formulas 5-1 to 5-6 or a functional group of the following formula 6, 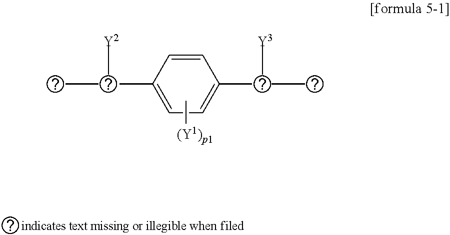
wherein Y¹ to Y³ of formula 5-1 are the same or different, and each hydrogen, a C₁ to C₁₀ alkyl group, or a functional group of the following formula 6, at least one of Y¹ to Y³ is the functional group of the following formula 6, p₁ is an integer of 0 to 4, m₁ and m₂ are the same or different and an integer of 0 to 3, all of p₁, m₁, and m₂ are not 0, and R and R′ are hydrogen or a C₁ to C₁₀ alkyl group, 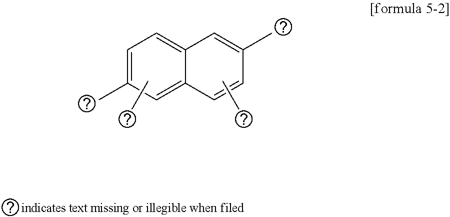
wherein Y⁴ and Y⁵ of formula 5-2 are the same or different, and each hydrogen, a C₁ to C₁₀ alkyl group, or a functional group of the following formula 6, at least one of Y⁴ and Y⁵ is the functional group of the following formula 6, and p₂ and p₃ are an integer of 0 to 3 and both are not 0, 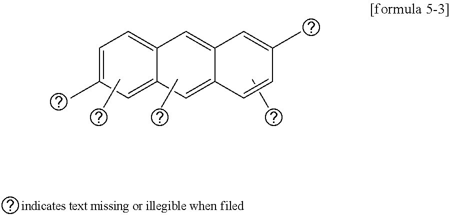
wherein Y⁶ to Y⁸ of formula 5-3 are the same or different, and each hydrogen, a C₁ to C₁₀ alkyl group or a functional group of the following formula 6, at least one of Y⁶ to Y⁸ is the functional group of the following formula 6, p₄ and p₆ are an integer of 0 to 3, p₅ is an integer of 0 to 2, and all of p₄, p₅, and p₆ are not 0, 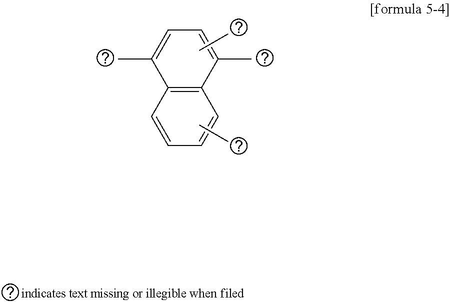
wherein Y⁹ and Y¹⁰ of formula 5-4 are the same or different, and each hydrogen, a C₁ to C₁₀ alkyl group, or a functional group of the following formula 6, at least one of Y⁹ and Y¹⁰ is the functional group of the following formula 6, and p₇ and p₈ are an integer of 0 to 2 and both are not 0, 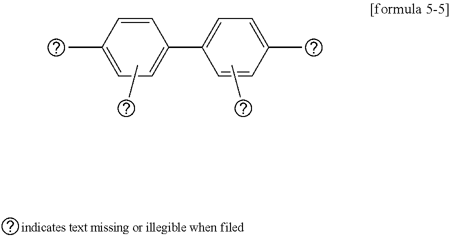
wherein Y¹¹ and Y¹² of formula 5-5 are the same or different, and each hydrogen, a C₁ to C₁₀ alkyl group, or a functional group of the following formula 6, at least one of Y¹¹ and Y¹² is the functional group of the following formula 6, and p₈ and p₁₀ are an integer of 0 to 4 and both are not 0, 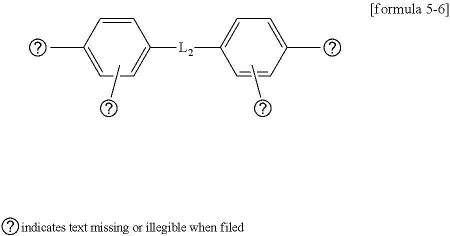
wherein Y¹³ and Y¹⁴ of formula 5-6 are the same or different, and each hydrogen, a C₁ to C₁₀ alkyl group, or a functional group of the following formula 6, at least one of Y¹³ and Y¹⁴ is the functional group of the following formula 6, p₁₁ and p₁₂ are an integer of 0 to 4, L₂ is an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of the following formula 6, or a divalent organic functional group of the following formulas 7-1 to 7-3, and both p₁₁ and p₁₂ are not 0 when L₂ is not substituted with the functional group of the following formula 6, and
in formulas 5-1 to 5-6, at least one hydrogen of the aromatic rings may be substituted with a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is defined in formula 1), 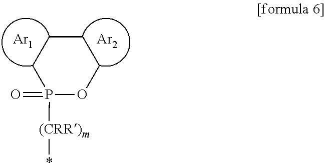
wherein Ar₁ and Ar₂ of formula 6 are a C₄ to C₃₀ substituted or unsubstituted aromatic ring group, R and R′ are the same or different and each hydrogen, a C₁ to C₂₀ alkyl group, or a C₆ to C₃₀ aryl group, and m is an integer of 0 to 3, 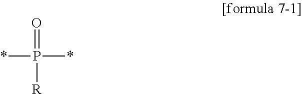
wherein R of formula 7-1 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group, 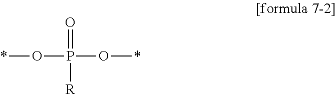
wherein R of formula 7-2 is hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, or a substituted or unsubstituted C₆ to C₃₀ aryloxy group

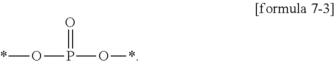

2. The insulating resin composition according to claim 1, wherein the liquid crystal oligomer has a number average molecular weight of 500 to 10,000 g/mol.

3. The insulating resin composition according to claim 1, wherein the structure unit of the formula 1 is included in an amount of 5 to 60 mol % based on a total amount of the liquid crystal oligomer, and the structure unit of the formula 2 is included in an amount of 40 to 95 mol % based on the total amount of the liquid crystal oligomer.

4. The insulating resin composition according to claim 1, wherein L₁ of the formula 4-7 is an ether group, a sulfide group, a ketone group, sulfoxide, a sulfone group, an azo group, a cyanide group, a substituted or unsubstituted C₁ to C₂₀ alkylene group, a substituted or unsubstituted C₁ to C₂₀ alkenylene group, or a substituted or unsubstituted C₆ to C₃₀ arylene group.

5. The insulating resin composition according to claim 1, wherein L₂ of the formula 5-6 is an ether group, a sulfide group, a ketone group, an amide group, sulfoxide, a sulfone group, an azo group, a cyanide group, a substituted or unsubstituted C₁ to C₂₀ alkylene group, a substituted or unsubstituted C₂ to C₂₀ alkenylene group, a substituted or unsubstituted C₆ to C₃₀ arylene group, a divalent organic functional group substituted or not substituted with at least one functional group of the formula 6, or a divalent organic functional group of the formulas 7-1 to 7-3.

6. The insulating resin composition according to claim 1, wherein the formula 6 is shown in the following formula 11: 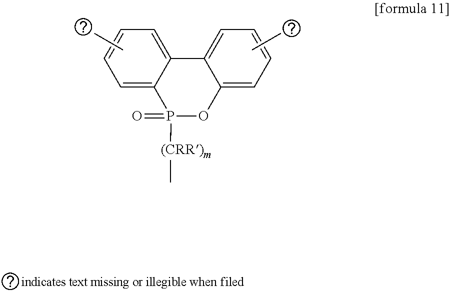
wherein R¹ and R² of formula 11 are the same or different, and each hydrogen, a halogen, a substituted or unsubstituted C₁ to C₂₀ alkyl group, a substituted or unsubstituted C₁ to C₂₀ alkoxy group, a substituted or unsubstituted C₃ to C₂₀ cycloalkyl group, a substituted or unsubstituted C₆ to C₃₀ aryl group, a substituted or unsubstituted C₇ to C₃₀ arylalkyl group, a substituted or unsubstituted C₆ to C₃₀ aryloxy group, or Z₁ (Z₁ is as defined in the formula 1), p₁ and p₂ are an integer of 0 to 4, R and R′ are the same or different, and each hydrogen, a C₁ to C₂₀ alkyl group, or a C₆ to C₃₀ aryl group, and m is an integer of 0 to 3.

7. The insulating resin composition according to claim 1, wherein the liquid crystal oligomer is shown in the following formula 12: 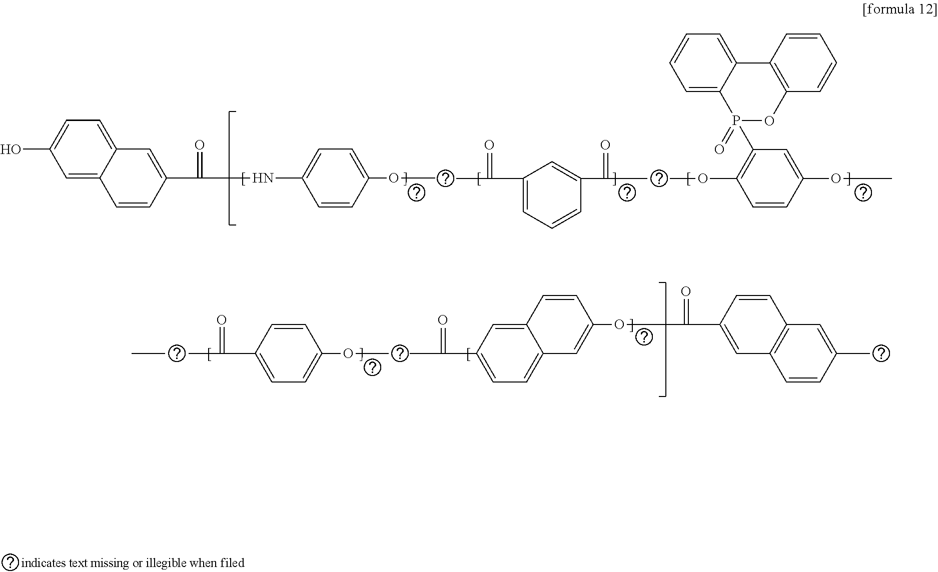
wherein a, b, c, d and e of the formula 12 mean a molar ratio of the structure unit and may be determined within the number average molecular weight of the liquid crystal oligomer.

8. The insulating resin composition according to claim 7, wherein the liquid crystal oligomer has the number average molecular weight of 2000 to 5000 g/mol.

9. The insulating resin composition according to claim 1, wherein the epxoy resin is one or more selected from the group consisting of a phenolic glycidyl ether type epoxy resin, a dicyclopentadiene type epoxy resin, a naphthalene type epoxy resin, a dihydroxybenzopyran type epoxy resin, a glycidylamine type epoxy resin, a triphenolmethane type epoxy resin, and a tetraphenylethane type epoxy resin.

10. The insulating resin composition according to claim 1, wherein the cyanate-based resin is shown in the following formula 13: 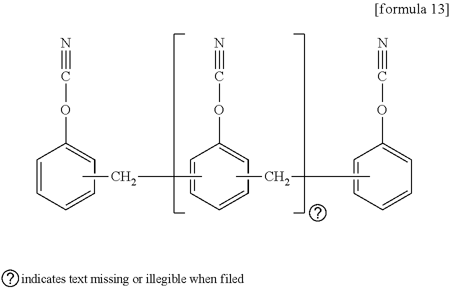
wherein n of the formula 13 is 2 to 7.

11. A copper clad laminate comprising:
an insulating layer including the insulating resin composition according to claim 1; and
a copper clad formed on at least one surface of upper and lower surfaces of the insulating layer.

12. The copper clad laminate according to claim 11, wherein the insulating layer further includes a reinforcing material.

13. A printed circuit board comprising:
an insulating layer including the insulating resin composition according to claim 1; and
a circuit pattern formed on the insulating layer.

14. The printed circuit board according to claim 13, wherein the insulating layer further includes a reinforcing material.
